(19) United States
(12) Patent Application Publication
(10) Pub. No.: US 2023/0366082 A1
(43) Pub. Date: Nov. 16, 2023

(54) FILM FORMING APPARATUS WITH ANNULAR EXHAUST DUCT

(71) Applicant: ASM IP Holding B.V., Almere (NL)

(72) Inventors: Jun Yoshikawa, Hachioji-shi (JP); Wei Chen Liao, Hachioji-shi (JP)

(21) Appl. No.: 18/195,456

(22) Filed: May 10, 2023

Related U.S. Application Data
(60) Provisional application No. 63/341,719, filed on May 13, 2022.

(51) Int. Cl. C23C 16/44; C23C 16/458; C23C 16/455; C23C 16/50

(52) U.S. Cl. CPC C23C 16/4412; C23C 16/4586; C23C 16/45565; C23C 16/50; C23C 16/45536

(57) ABSTRACT

A film forming apparatus includes a chamber, a susceptor placed in the chamber, an electrode placed inside the susceptor, a conductive shower head arranged above the susceptor apart from each other, an annular exhaust duct arranged so as to surround the outer edge of the susceptor, and an AC power supply that supplies AC power to the electrode, wherein the annular exhaust duct has an exhaust gas introduction member having an exhaust gas inlet and an exhaust gas discharge member having an exhaust gas outlet, the exhaust gas introduction member is arranged on the susceptor side in the radial direction of the susceptor and is made of an insulating material, and the exhaust gas discharge member is arranged on the side opposite to the susceptor side in the radial direction of the susceptor, and is made of a conductive material.

### CROSS-REFERENCE TO RELATED APPLICATIONS

This application claims priority to U.S. Provisional Patent Application Ser. No. 63/341,719 filed May 13, 2022 titled FILM FORMING APPARATUS WITH ANNULAR EXHAUST DUCT, the disclosure of which is hereby incorporated by reference in its entirety.

### BACKGROUND OF THE INVENTION

### Field of the Invention

The present disclosure relates to a film forming apparatus.

### Description of Related Art

As a film forming apparatus, an apparatus having a susceptor on which an object to be film-formed (for example, a wafer) is placed and a shower head arranged above the susceptor apart from each other in a chamber is known. In this film forming apparatus, a thin film is formed on the surface of the object to be film-formed by using a source gas supplied from the shower head. As an exhaust duct for exhausting the source gas supplied from the shower head to the outside, the annular exhaust duct having an exhaust gas inlet arranged so as to surround the outer edge of the susceptor and provided on the surface on the susceptor side, and an exhaust gas outlet provided on the surface opposite to the exhaust gas inlet, is known (see, U.S. Pat. No. 9,673,092).

As the film forming apparatus, a plasma forming apparatus is used. In the plasma film forming apparatus, AC power is applied to a source gas supplied from the shower head to dissociate the source gas into a plasma state, thereby promoting the formation of a thin film.

In the plasma film forming apparatus, there are a type in which a shower head is made to be conductive and the AC power applying to a source gas is supplied to a conductive shower head, and a type in which electrodes are placed inside the susceptor and the AC power is supplied to the electrodes. In the film forming device of the type that supplies AC power to electrodes placed inside the susceptor, if the annular exhaust duct is made of a conductive material, a strong electric field is generated between the electrodes inside the susceptor and the annular exhaust duct, and parasitic plasma may be generated around the exhaust duct. On the other hand, if the annular exhaust duct is made of an insulating material such as ceramic, a strong electric field is generated in a place other than around the annular exhaust duct, such as inside the connection portion between the shower head and a source gas supply pipe that supplies the source gas to the shower head, and parasitic plasma may be generated.

### SUMMARY OF THE INVENTION

An aspect of the present disclosure provides a film forming apparatus, including a chamber, a susceptor placed in the chamber, an electrode placed inside the susceptor, a conductive shower head spaced above the susceptor, an annular exhaust duct arranged so as to surround the outer edge of the susceptor, and an AC power supply that supplies AC power to the electrode, wherein the annular exhaust duct has an exhaust gas introduction member having an exhaust gas inlet and an exhaust gas discharge member having an exhaust gas outlet, the exhaust gas introduction member is arranged on the susceptor side in the radial direction of the susceptor and is made of an insulating material, and the exhaust gas discharge member is arranged on the side opposite to the susceptor side in the radial direction of the susceptor, and is made of a conductive material.

In the film forming apparatus according to the aspect, the exhaust gas introduction member may have an inclined portion that rises outward from the susceptor side in a side view, and the exhaust gas discharge member may be engaged with the radial end of the inclined portion of the exhaust gas introducing member.

In the film forming apparatus according to the aspect, the exhaust gas discharge member of the annular exhaust duct may be in contact with the conductive shower head, and at least one of the exhaust gas discharge member and the conductive shower head may be connected to the ground wiring.

### BRIEF DESCRIPTION OF THE DRAWINGS

FIG. 1 is a cross-sectional view showing an example of a chamber of a film forming apparatus according to an embodiment of the present disclosure.

FIG. 2 is a cross-sectional view showing another example of the chamber of the film forming apparatus according to an embodiment of the present disclosure.

FIG. 3 is a cross-sectional view showing the periphery of the annular exhaust duct of the film forming apparatus shown in FIG. 1.

FIG. 4 is the result of the electric field simulation showing an electric field around the annular exhaust duct shown in FIG. 3.

FIG. 5 is a cross-sectional view showing the periphery of the annular exhaust duct of the film forming apparatus shown in FIG. 2.

FIG. 6 is the result of the electric field simulation showing an electric field around the annular exhaust duct shown in FIG. 5.

FIG. 7 is an enlarged view showing the periphery of the annular exhaust duct formed of a perfect conductor.

FIG. 8 is the result of the electric field simulation showing an electric field around the annular exhaust duct shown in FIG. 7.

### DETAILED DESCRIPTION OF THE INVENTION

Hereinafter, the present disclosure will be described in detail with reference to the drawings as appropriate. The drawings used in the following description may be enlarged for convenience in order to make the features of the present disclosure easy to understand, and the dimensional ratio of each component may differ from the actual one. The materials, dimensions, etc. exemplified in the following description are examples, and the present disclosure is not limited thereto and it is possible to appropriately change and implement the present disclosure within a range in which the effects of the present disclosure can be obtained.

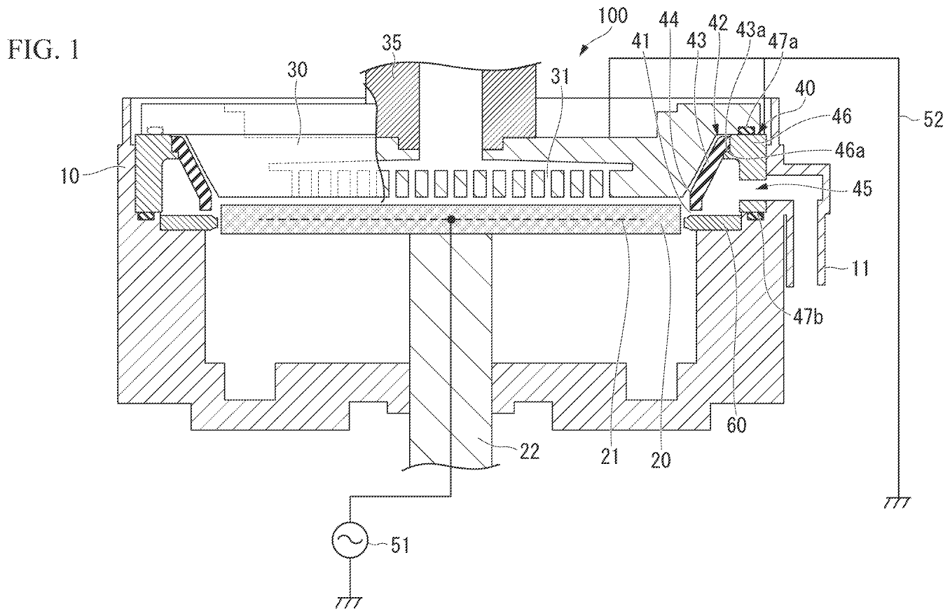

FIG. 1 is a cross-sectional view showing an example of a chamber of a film forming apparatus according to an embodiment of the present disclosure. The film forming apparatus 100 shown in FIG. 1 includes a chamber 10, a susceptor 20 placed in the chamber 10, an electrode 21 placed inside the susceptor 20, a conductive shower head 30 spaced above the susceptor 20, an annular exhaust duct 40 arranged so as to surround the outer edge of the susceptor, and an AC power supply 51 that supplies AC power to the electrode 21.

The susceptor 20 is circular in a plan view. The center of the susceptor 20 is supported by the susceptor support portion 22. The materials of the susceptor 20 and the susceptor support 22 is, for example, a ceramic such as alumina or aluminum nitride. In the susceptor 20, the surface thereof on the side of the conductive shower head 30 is a mounting surface on which an object to be film-formed is placed. Inside the susceptor 20, a heater (not shown) for heating the placed object to be film-formed is provided.

The shape of the electrode 21 arranged inside the susceptor 20 is, for example, a plate shape, a wire mesh shape, or a punching metal shape. The material of the electrode 21 is, for example, a high melting metal such as tungsten, tantalum, molybdenum, niobium, ruthenium, and hafnium.

The conductive shower head 30 has a plurality of through gas holes 31. The material of the conductive shower head 30 is, for example, stainless steel. The conductive shower head 30 is connected to the source gas supply pipe 35. The source gas supplied from the source gas supply pipe 35 is discharged toward the susceptor 20 (the film-formed object placed on the susceptor 20) through the through gas holes 31.

The annular exhaust duct 40 has an exhaust gas introduction member 42 having an exhaust gas inlet 41 and an exhaust gas discharge member 46 having an exhaust gas outlet 45.

The exhaust gas introduction member 42 is arranged on the susceptor 20 side in the radial direction of the susceptor 20. The exhaust gas introduction member 42 has an inclined portion 43 that rises outward from the susceptor 20 side in a side view, and a vertical portion 44 at the tip of the exhaust gas introduction member 42 on the susceptor 20 side. The inclined portion 43 has a recess 43a at the radial end portion. A flow control ring (FCR) 60 is arranged below the vertical portion 44, and the exhaust gas inlet 41 is formed between the vertical portion 44 and the FCR 60. The exhaust gas introduction member 42 is made of an insulating material. The exhaust gas introduction member 42 may be made of only an insulating material. As the material of the exhaust gas introducing member 42, a ceramic (dielectric) having a relative permittivity of 3 or more and 20 or less can be used. Examples of the material of the exhaust gas introducing member 42 include alumina (Al₂O₃), quartz (SiO₂), and aluminum nitride (AlN).

The exhaust gas discharge member 46 is arranged on the side opposite to the susceptor 20 side in the radial direction of the susceptor 20. The exhaust gas discharge member 46 has a convex portion 46a at the end on the exhaust gas introduction member 42 side. The exhaust gas introduction member 42 and the exhaust gas discharge member 46 are engaged with each other by engaging the concave portion 43a of the inclined portion 43 of the exhaust gas introduction member 42 and the convex portion 46a of the exhaust gas discharge member 46. However, the exhaust gas introduction member 42 and the exhaust gas discharge member 46 may be engaged as long as they are engaged so that the exhaust gas does not flow out, and there is no particular limitation on the method of engaging the two. The exhaust gas discharge member 46 is made of a conductive material. The exhaust gas discharge member 46 may be made of only a conductive material. As the material of the exhaust gas discharge member 46, stainless steel, iron, aluminum, tungsten, tantalum, molybdenum, niobium, ruthenium, hafnium and the like can be used. The exhaust gas outlet 45 of the exhaust gas discharge member 46 is connected to the exhaust port 11 of the chamber 10.

The shortest distance between the exhaust gas inlet 41 of the annular exhaust duct 40 and the susceptor 20 is, for example, within the range of 10 mm or more and 30 mm or less.

An O-ring 47a is arranged between the chamber 10 and the upper surface of the exhaust gas discharge member 46 of the annular exhaust duct 40. An O-ring 47b is arranged between the lower surface of the exhaust gas discharge member 46 of the annular exhaust duct 40 and the chamber 10.

The AC power supply 51 is connected to the electrode 21 and supplies AC power to the electrode 21. The exhaust gas discharge member 46 of the conductive shower head 30 and the annular exhaust duct 40 are connected to the ground wiring 52, respectively. Therefore, by supplying AC power to the electrode 21, an AC electric field is generated between the electrode 21 and the conductive shower head 30, and between the electrode 21 and the exhaust gas discharge member 46 of the annular exhaust duct 40. As a result, the source gas released from the through gas holes 31 of the conductive shower head 30 is dissociated to be in a plasma state. The frequency of the AC power supplied from the AC power source 51 to the electrode 21 is, for example, in the range of 10 MHz or more and 300 MHz or less, and particularly VHF (Very High Frequency) of 30 MHz or more and 300 MHz or less.

The FCR 60 surrounds the susceptor 20 with a gap between it and the side surface of the susceptor 20. A seal gas and a process gas introduced from below the chamber 10 flow between the FCR 60 and the susceptor 20. The seal gas has an effect of suppressing the source gas released from the conductive shower head 30 from flowing below the chamber 10 through the gap between the FCR 60 and the susceptor 20. A noble gas can be used as the sealing gas. As the material of FCR60, for example, ceramics such as alumina, quartz and aluminum nitride, and metals such as aluminum and titanium can be used.

The film forming process of the film forming processing apparatus 100 is performed as follows.

The object to be film-formed is placed on the susceptor 20. The object to be film-formed is, for example, a silicon wafer. Next, the object to be film-formed is heated by a heater provided inside the susceptor 20. Next, while discharging the source gas supplied from the source gas supply pipe 35 toward the susceptor 20 (that is, the object to be film-formed) through the through gas holes 31, AC power is supplied to the electrode 21 using the AC power supply 51. By supplying AC power to the electrode 21, the source gas is dissociated into a plasma state, and a thin film is formed on the surface of the object to be film-formed. The source gas flows into the annular exhaust duct 40 through the exhaust gas inlet 41. The source gas flowing into the annular exhaust duct 40 passes through the exhaust gas outlet 45 and is exhausted to the outside through the exhaust port 11 of the chamber 10.

In the film forming apparatus 100 of the present embodiment having the above configuration, since the exhaust gas discharge member 46 having the exhaust gas inlet 41 of the annular exhaust duct 40 is made of an insulating material, an AC electric field is unlikely to generate between the electrode 21 of the susceptor 20 and the exhaust gas inlet 41 of the annular exhaust duct 40. Therefore, according to the film forming apparatus 100 of the present embodiment, parasitic plasma is unlikely to be generated around the exhaust gas inlet 41 of the annular exhaust duct 40. Further, the exhaust gas discharge member 46 having the exhaust gas outlet 45 of the annular exhaust duct 40 is made of a conductive material, and the conductive shower head 30 and the exhaust gas discharge member 46 are connected to the ground wiring 52, respectively, and for these, an electric field is unlikely to be generated between the conductive shower head 30 and the annular exhaust duct 40. When the conductive shower head 30 and the exhaust gas discharge member 46 of the annular exhaust duct 40 are electrically connected, only one of the conductive shower head 30 and the exhaust gas introduction member may be connected to the ground wiring 52.

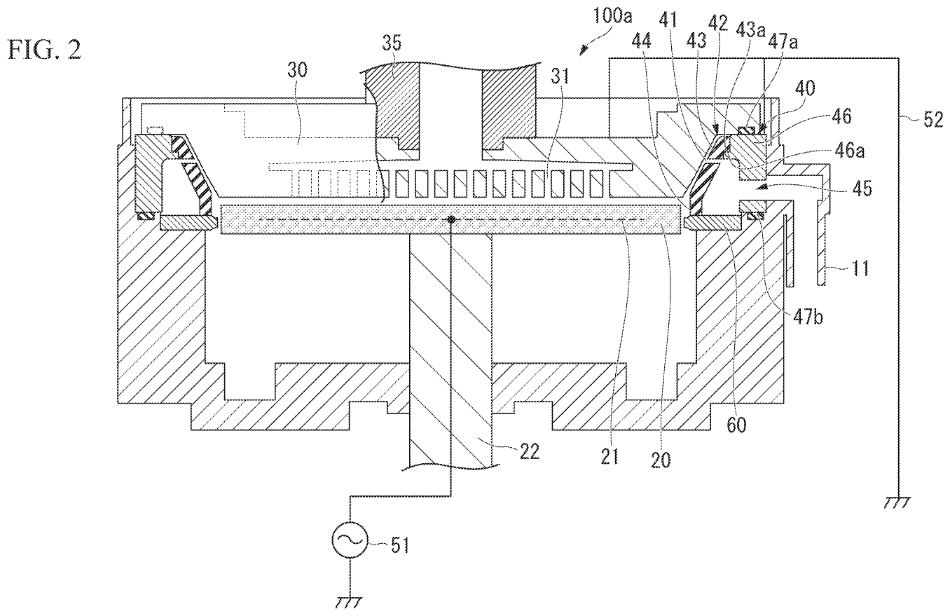

In the film forming apparatus 100 of the present embodiment, the exhaust gas inlet 41 of the annular exhaust duct 40 is formed between the vertical portion 44 of the exhaust gas introduction member 42 and the FCR 60, but the position of the exhaust gas inlet 41 is not limited to this. FIG. 2 is a cross-sectional view showing another example of the chamber of the film forming apparatus according to the embodiment of the present disclosure.

In the film forming apparatus 100a shown in FIG. 2, the vertical portion 44 of the exhaust gas introduction member 42 of the annular exhaust duct 40a is in contact with the FCR 60, the exhaust gas inlet 41a is formed in the inclined portion 43 of the exhaust gas introduction member 42, and is arranged at a position above the lower end of the conductive shower head 30. Since the film forming apparatus 100a is the same as the film forming apparatus 100 shown in FIG. 1 except for the position of the exhaust gas inlet 41a, the same parts as the film forming apparatus 100 are designated by the same reference numerals, and detailed explanation will be omitted.

The film forming apparatus 100a exhibits the same effect as the film forming apparatus 100 because the annular exhaust duct 40a includes an exhaust gas introducing member 42 having an exhaust gas introducing hole 41a and an exhaust gas discharge member 46 having an exhaust gas outlet 45.

The film forming apparatus according to the present disclosure may be, for example, a plasma CVD apparatus or a plasma ALD apparatus.

Next, the result of confirming the effect of the present disclosure by the electric field simulation will be described.

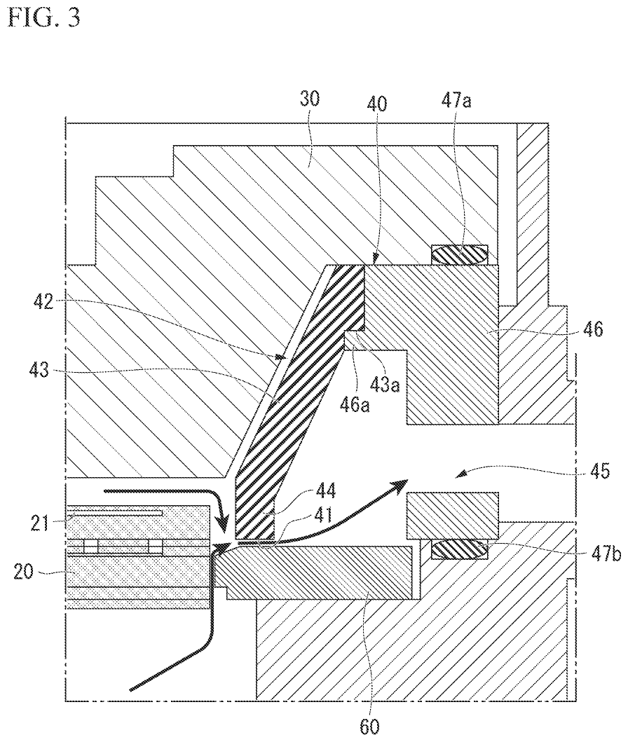

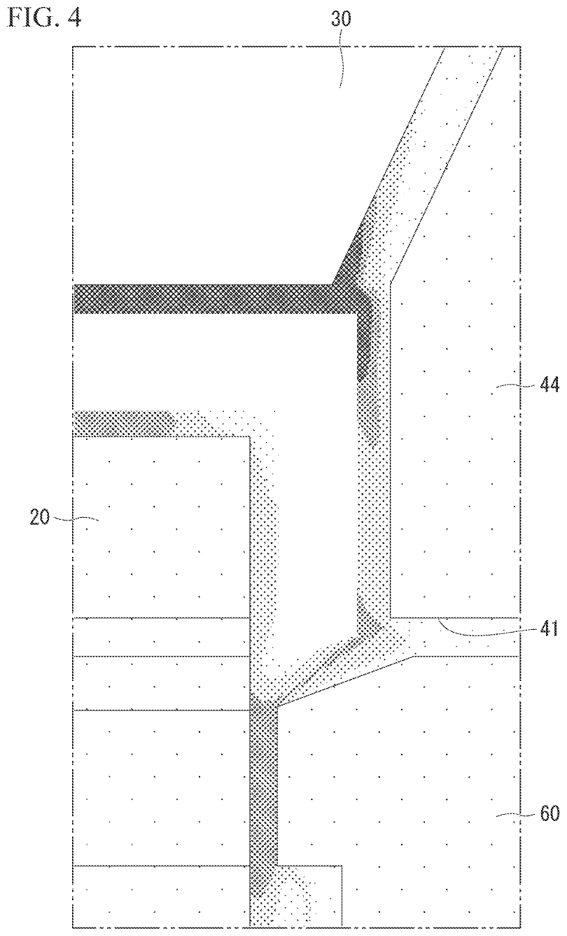

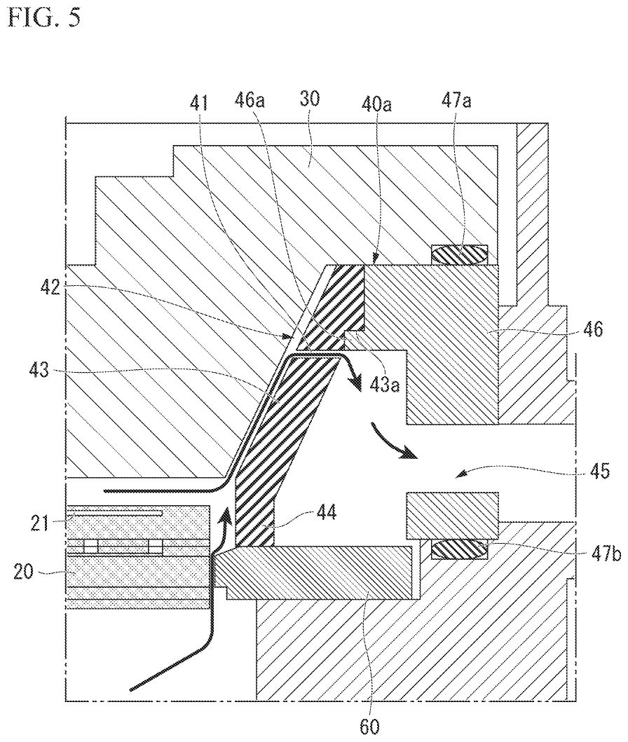

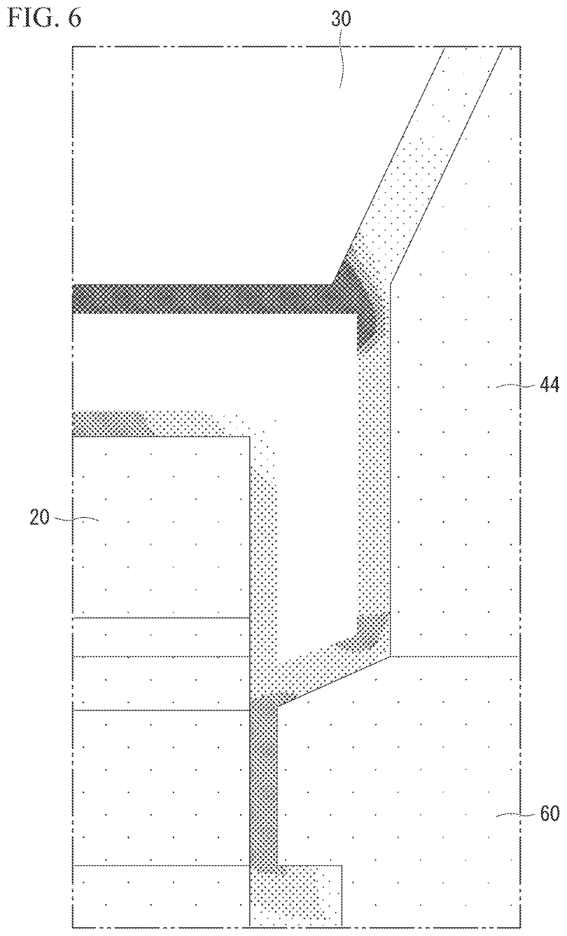

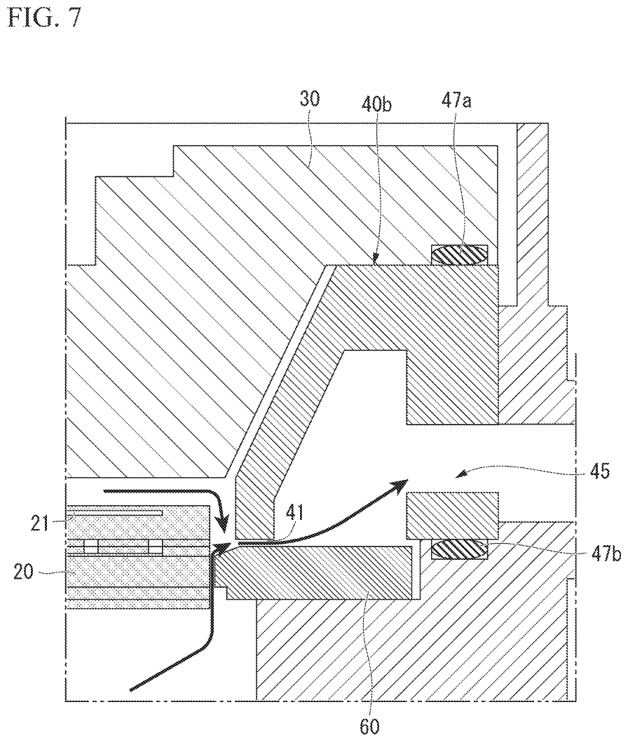

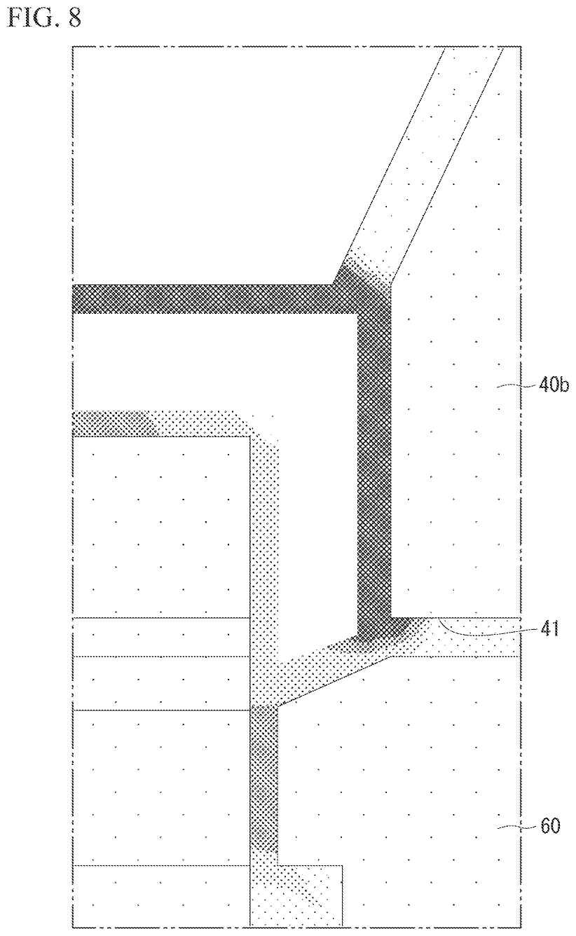

FIG. 3 is a cross-sectional view showing the periphery of the annular exhaust duct of the film forming apparatus shown in FIG. 1, and FIG. 4 is the result of the electric field simulation showing an electric field around the annular exhaust duct shown in FIG. 3. FIG. 5 is a cross-sectional view showing the periphery of the annular exhaust duct of the film forming apparatus shown in FIG. 2, and FIG. 6 is the result of the electric field simulation showing an electric field around the annular exhaust duct shown in FIG. 5. FIG. 7 is an enlarged view showing the periphery of the annular exhaust duct formed of a perfect conductor, and FIG. 8 is the result of the electric field simulation showing an electric field around the annular exhaust duct shown in FIG. 7. The annular exhaust duct 40b shown in FIG. 7 has the same configuration as the annular exhaust duct 40 shown in FIG. 3, except that the annular exhaust duct 40b is integrally formed of a perfect conductor.

In FIGS. 3, 5 and 6, the arrows indicate the flow of gas. As shown in FIG. 3, the source gas discharged from the conductive shower head 30 and the seal gas flowing between the FCR 60 and the susceptor 20 pass through the exhaust gas inlet 41 of the annular exhaust duct 40 and enter the inside of the annular exhaust duct 40. Similarly, in the case of the annular exhaust duct 40a shown in FIG. 5 and the annular exhaust duct 40b shown in FIG. 7, the source gas and the seal gas flow into the inside of the annular exhaust ducts 40a and 40b through the exhaust gas inlets 41a and 41b.

The electric field simulation was performed by a simulation considering the sheath region. In the calculation of the electric field simulation, the material of the exhaust gas introduction member 42 of the annular exhaust duct 40 shown in FIG. 3 and the exhaust gas introduction member 42 of the annular exhaust duct 40a shown in FIG. 5 was Al₂O₃ (relative permittivity: 9). The material of FCR60 was Al₂O₃ (relative permittivity: 9).

In FIGS. 4, 6 and 8, the dark-colored portion (the portion where the dots are dense) indicates that the electric field strength is high. From the results of FIGS. 4, 6 and 8, it can be seen that the surface of the conductive shower head 30 has a strong electric field strength and plasma is easily generated. On the other hand, in the annular exhaust duct 40 shown in FIG. 4 and the annular exhaust duct 40a shown in FIG. 6, the electric field strength on the surface of the exhaust gas introducing member 42 in contact with the gap between the susceptor 20 and the conductive shower head 30 is weak, and for this, it can be seen that the generation of plasma is spontaneously suppressed in this part. That is, in the annular exhaust duct 40 of FIG. 4 and the annular exhaust duct 40a of FIG. 6, the generation of plasma originating from the portion in contact with the gap between the susceptor 20 and the conductive shower head 30 is suppressed, and as a result, it can be seen that the parasitic plasma at the lower part of the susceptor 20 is suppressed. On the other hand, the annular exhaust duct 40b shown in FIG. 8 has a strong electric field strength on the surface of the portion in contact with the gap between the susceptor 20 and the conductive shower head 30, and it can be seen that plasma is easily generated. That is, in the annular exhaust duct 40b shown in FIG. 8, plasma is generated starting from the portion in contact with the gap between the susceptor 20 and the conductive shower head 30, and as a result, it can be seen that parasitic plasma may be generated at the lower portion of the susceptor 20 near the portion.

What is claimed is:

1. A film forming apparatus, comprising:
a chamber;
a susceptor placed in the chamber;
an electrode placed inside the susceptor;
a conductive shower head arranged above the susceptor apart from each other;
an annular exhaust duct arranged so as to surround the outer edge of the susceptor; and,
an AC power supply that supplies AC power to the electrode,
wherein the annular exhaust duct has an exhaust gas introduction member having an exhaust gas inlet and an exhaust gas discharge member having an exhaust gas outlet, the exhaust gas introduction member is arranged on the susceptor side in the radial direction of the susceptor and is made of an insulating material, and the exhaust gas discharge member is arranged on the side opposite to the susceptor side in the radial direction of the susceptor, and is made of a conductive material.

2. The film forming apparatus according to claim 1,
wherein the exhaust gas introduction member has an inclined portion that rises outward from the susceptor side in a side view, and the exhaust gas discharge member is engaged with the radial end of the inclined portion of the exhaust gas introducing member.

3. The film forming apparatus according to claim 1,
wherein the exhaust gas discharge member of the annular exhaust duct is in contact with the conductive shower head, and at least one of the exhaust gas discharge member and the conductive shower head is connected to the ground wiring.

4. The film forming apparatus according to claim 1,
wherein the exhaust gas inlet is formed between the exhaust gas introduction member and the FCR.

5. The film forming apparatus according to claim 2,
wherein the exhaust gas inlet is formed in the inclined portion.

6. The film forming apparatus according to claim 1,
wherein the exhaust gas introduction member is made of a material selected from the group consisting of alumina (Al₂O₃), quartz (SiO₂) and aluminum nitride (AlN).

7. The film forming apparatus according to claim 1,
wherein the exhaust gas discharge member is made of a material selected from the group consisting of stainless steel, iron, aluminum, tungsten, tantalum, molybdenum, niobium, ruthenium, and hafnium.

8. The film forming apparatus according to claim 1,
wherein the shortest distance between the exhaust gas inlet and the susceptor is within the range of 10 mm or more and 30 mm or less.
